(19) United States
(12) Patent Application Publication
(10) Pub. No.: US 2026/0156930 A1
(43) Pub. Date: Jun. 4, 2026

(54) THRESHOLD VOLTAGE TARGETING IN STACKED FET

(71) Applicant: International Business Machines Corporation, Armonk, NY (US)

(72) Inventors: Kishwar Mashooq, Albany, NY (US); Paul Charles Jamison, Averill Park, NY (US); Takashi Ando, Eastchester, NY (US); Ruilong Xie, Niskayuna, NY (US); Shay Reboh, Guilderland, NY (US)

(21) Appl. No.: 18/965,398

(22) Filed: Dec. 2, 2024

(51) Int. Cl. H01L 21/02

(52) U.S. Cl. CPC H10D 84/851; H10D 84/0167; H10D 84/0177

(57) ABSTRACT

A semiconductor device is disclosed including a stacked field effect transistor (PET) having a targeted threshold voltage in which one transistor of the stacked FET contains an Al-containing alloy layer that surrounds at least two, but not all, faces of each individual semiconductor channel material nanosheet of a stack of nanosheets.

### BACKGROUND

The present application relates to semiconductor technology, and more particularly to a semiconductor device including a stacked field effect transistor (FET) having a targeted threshold voltage.

A stacked FET is a configuration in which two FETs are vertically integrated on a semiconductor substrate. These FETs are stacked vertically on top of each other resulting in a compact structure that combines the individual benefits of each of the FETs. Stacked FETs can include two nFETs stacked one atop the other, two pFETs stacked one atop the other or an nFET and a pFET stacked one atop the other (e.g., pFET stacked over the nFET, or nFET stacked over the pFET). Stacked FETs have a reduced footprint and an increased efficiency compared to non-stacked FETs. The increased efficiency can include, for example, a lower on-state resistance, a lower gate charge and/or a parasitic inductance resistance.

### SUMMARY

A semiconductor device is disclosed including a stacked FET having a targeted threshold voltage in which one transistor of the stacked FET contains an Al-containing alloy layer that surrounds at least two, but not all, faces of each individual semiconductor channel material nanosheet of a stack of nanosheets. The presence of the Al-containing alloy layer removes oxygen defects from a gate dielectric layer that also surrounds each individual semiconductor channel material nanosheet of the stack of nanosheets, and the Al-containing alloy layer can also set the threshold voltage of the transistor containing the same.

In one aspect of the present application, a semiconductor device is provided. In one embodiment of the present application, the semiconductor device includes a second transistor stacked over a first transistor in which one of the first transistor or the second transistor includes a plurality of spaced apart nFET semiconductor channel material nanosheets having an Al-containing alloy layer surrounding at least two, but not all, faces of each nFET semiconductor channel material nanosheet of the plurality of spaced apart nFET semiconductor channel material nanosheets.

In another embodiment of the present application, the semiconductor device includes a first transistor including a plurality of spaced apart nFET semiconductor channel material nanosheets having an Al-containing alloy layer surrounding at least two, but not all, faces of each nFET semiconductor channel material nanosheet of the plurality of spaced apart nFET semiconductor channel material nanosheets; a second transistor stacked over the first transistor in which the second transistor includes a plurality of spaced apart pFET semiconductor channel material nanosheets; and a middle dielectric isolation layer located between the first transistor and the second transistor.

In a further embodiment of the present application, the device includes a first transistor including a plurality of spaced apart pFET semiconductor channel material nanosheets; a second transistor stacked over the first transistor, in which the second transistor includes a plurality of spaced apart nFET semiconductor channel material nanosheets having an Al-containing alloy layer surrounding at least two, but not all, faces of each nFET semiconductor channel material nanosheet of the plurality of spaced apart nFET semiconductor channel material nanosheets; and a middle dielectric isolation layer located between the first transistor and the second transistor.

### BRIEF DESCRIPTION OF THE DRAWINGS

FIGS. 1A-1D are cross sectional views illustrating various semiconductor devices in accordance with the present application in which a pFET is stacked over an nFET.

FIGS. 2A-2D are cross sectional views illustrating various semiconductor devices in accordance with the present application in which an nFET is stacked over a pFET.

FIG. 3 is a cross sectional view of an initial structure that can be employed in forming a semiconductor device in accordance with the present application, the initial structure including an nFET material stack of alternating layers of nFET sacrificial semiconductor material layers and nFET semiconductor channel material layers, and a pFET material stack of alternating layers of pFET sacrificial semiconductor material layers and pFET semiconductor channel material layers, in which the nFET material stack is vertically spaced apart from the pFET material stack by a sacrificial semiconductor material layer.

FIG. 4 is a cross sectional view of the initial structure of FIG. 3 after forming a sacrificial gate structure, and then etching the nFET material stack, the sacrificial semiconductor material layer, and the second material utilizing the sacrificial gate structure as an etch mask to provide an nFET nanosheet stack of alternating nanosheets of nFET sacrificial semiconductor material nanosheets and nFET semiconductor channel material nanosheets, and a pFET nanosheet stack of alternating nanosheets of pFET sacrificial semiconductor material nanosheets and pFET semiconductor channel material nanosheets, in which the nFET nanosheet stack is vertically spaced apart from the pFET nanosheet stack by a patterned sacrificial semiconductor material layer.

FIG. 5 is a cross sectional view of the structure of FIG. 4 after replacing the patterned sacrificial semiconductor material layer with a middle dielectric isolation layer.

FIG. 6 is a cross sectional view of the structure of FIG. 5 after performing a gate cut process.

FIG. 7 is a cross sectional view of the structure of FIG. 6 after removing the sacrificial gate structure.

FIG. 8 is a cross sectional view of the structure of FIG. 7 after removing each of the nFET sacrificial semiconductor material nanosheets and each of the pFET sacrificial semiconductor material nanosheets to suspend a portion of each of the nFET semiconductor channel material nanosheets and each of the pFET semiconductor channel material nanosheets, respectively, and forming a gate dielectric layer on a suspended portion of each of the nFET semiconductor channel material nanosheets and each of the pFET semiconductor channel material nanosheets.

FIG. 9 is a cross sectional view of the structure of FIG. 8 after forming a bottom n-type threshold voltage setting work function metal layer, an Al-containing alloy layer, and a top n-type threshold voltage setting work function metal layer.

FIG. 10 is a cross sectional view of the structure of FIG. 9 after forming an organic dielectric layer.

FIG. 11 is a cross sectional view of the structure of FIG. 10 after recessing the organic dielectric layer to physically expose a pFET device area including the pFET nanosheet stack.

FIG. 12 is a cross sectional view of the structure of FIG. 11 after removing the bottom n-type threshold voltage setting work function metal layer, the Al-containing alloy layer, and the top n-type threshold voltage setting work function metal layer from the pFET device area.

FIG. 13 is a cross sectional view of the structure of FIG. 12 after forming a p-type threshold voltage setting work function metal layer, removing a remaining portion of the organic dielectric layer, and then forming a gate electrode and a gate cap.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

The terms substantially, substantially similar, about, or any other term denoting functionally equivalent similarities refer to instances in which the difference in length, height, or orientation convey no practical difference between the definite recitation (e.g., the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

To minimize capacitance in a semiconductor device containing a nanosheet transistor including, for example, stacked nanosheet transistors, it is desired to minimize the distance between the suspended portion of one semiconductor channel material nanosheet to the suspended portion of the nearest neighboring semiconductor channel material nanosheet in a nanosheet stack. The distance beneath the suspended portion of each semiconductor channel material nanosheet is oftentimes referred to as Tsus. Notably, Tsus denotes a thickness (or height) that is present beneath the suspended portion of each semiconductor channel material nanosheet. However, when Tsus is too small, some threshold voltage (Vt) adjustments cannot be achieved because there is not enough space between the suspended semiconductor channel material nanosheets to fit in a work function metal (WFM) or alternative high-k gate dielectric layer. The term “threshold voltage” is used throughout the present application to denote the voltage that must be applied to the gate structure of a transistor to turn the transistor “on” and allow a significant current to flow between the source region and the drain region. There is a need for Vt targeting in a scaled FET with small Tsus (i.e., Tsus of 7 nm or less).

A transistor (or field effect transistor (FET)) includes a source region, a drain region, a semiconductor channel region located between the source region and the drain region, and a gate structure located above the semiconductor channel region. Collectively, the source region and the drain region can be referred to as a source/drain region. As used herein, a “source/drain” region can be a source region or a drain region depending on subsequent wiring and application of voltages during operation of the transistor. In the embodiment described in the present application, the transistor is a nanosheet transistor. A nanosheet transistor is a non-planar transistor that includes a vertical stack of spaced apart semiconductor channel material nanosheets as the semiconductor channel region with a pair of source/drain regions located at each of the ends of the vertical stack of spaced apart semiconductor channel material nanosheets. The gate structure includes a gate dielectric and a gate electrode. The gate structure wraps around each of the spaced apart semiconductor channel material nanosheets. Nanosheet transistors provide considerable scaling with high drive current capability. Nanosheet transistors provide a larger drive current for a given footprint compared to finFET technology.

In the present application, a semiconductor device including a stacked FET in which one nanosheet transistor is stacked over another nanosheet transistor is disclosed. As mentioned above, stacked FETs have a reduced footprint and an increased efficiency compared to non-stacked FETs. The increased efficiency can include, for example, a lower on-state resistance, a lower gate charge and/or a parasitic inductance resistance.

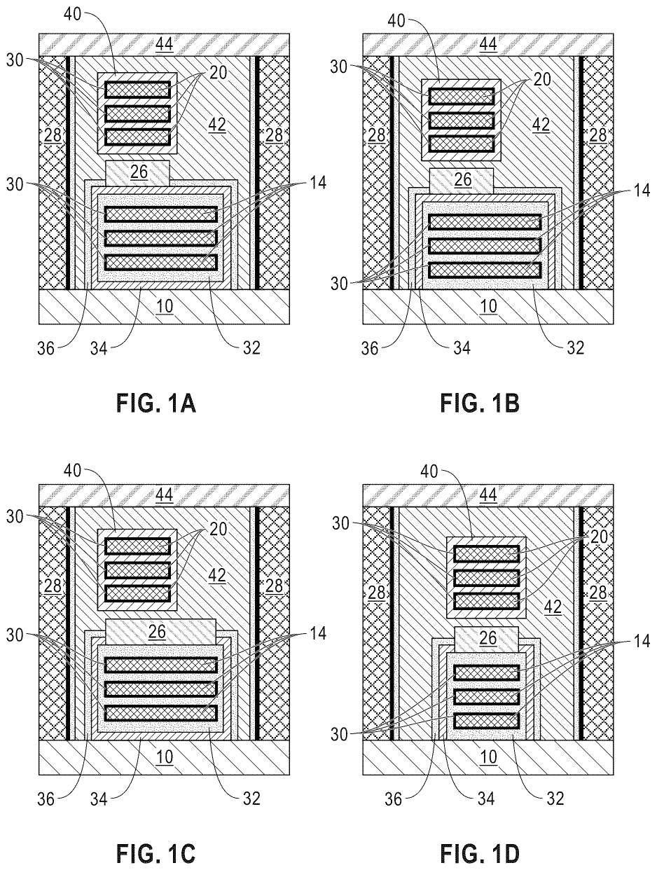

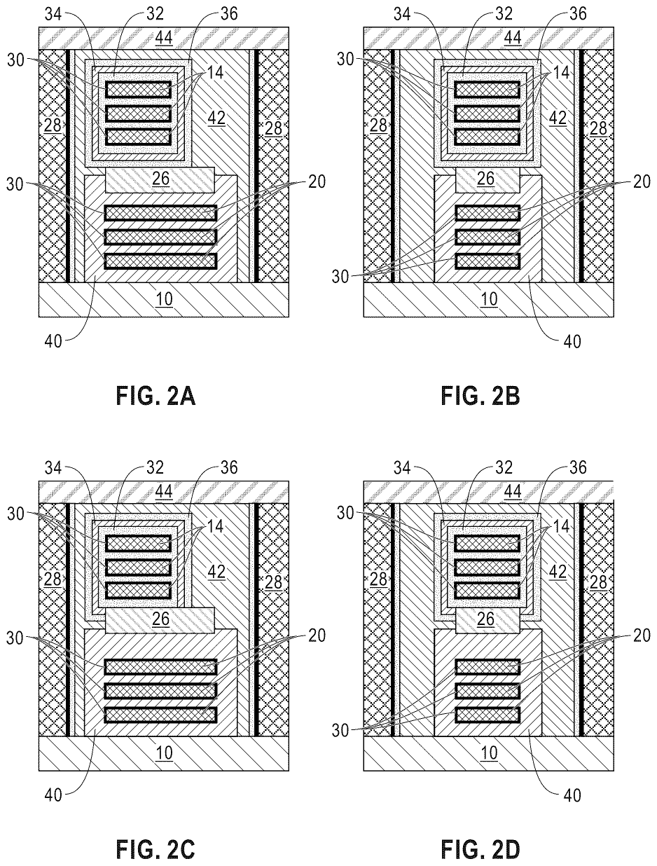

In one aspect of the present application, a semiconductor device (as illustrated in FIGS. 1A-1D and 2A-2D) is provided. In one embodiment of the present application, the semiconductor device includes a second transistor stacked over a first transistor in which one of the first transistor or the second transistor includes a plurality of spaced apart nFET semiconductor channel material nanosheets having Al-containing alloy layer 34 surrounding at least two as shown in 1B, but not all, faces of each nFET semiconductor channel material nanosheet 14 of the plurality of spaced apart nFET semiconductor channel material nanosheets. In the present application, the Al-containing layer 34 can surround two or three, but not four, faces of each nFET semiconductor channel material nanosheet 14.

In some embodiments (see, for example, FIGS. 1A-1D), the first transistor includes the Al-containing alloy layer 34. In other embodiments (see, for example, FIGS. 2A-2D), the second transistor includes the Al-containing alloy layer 34.

In some embodiments (see, for example, FIGS. 1A-1B and 2A-2B), the Al-containing alloy layer 34 surrounds three faces of each nFET semiconductor channel material nanosheet 14.

In some embodiments (see, for example, FIGS. 1D, 2B and 2D), the first transistor or the second transistor not including the Al-containing alloy layer 34 includes a plurality of spaced apart pFET semiconductor channel material nanosheets, in which each pFET semiconductor channel material nanosheet 20 of the plurality of spaced apart pFET semiconductor channel material nanosheets has a same length as each nFET semiconductor channel material nanosheet 14 of the plurality of spaced apart nFET semiconductor channel material nanosheets. In such embodiments, a I-shaped stacked FET is provided.

In some embodiments (see, for example, 1A-1C, 2A and 2C), the first transistor or the second transistor not including the Al-containing alloy layer 34 includes a plurality of spaced apart pFET semiconductor channel material nanosheets, in which each pFET semiconductor channel material nanosheet 20 of the plurality of spaced apart pFET semiconductor channel material nanosheets has a length that differs from a length of each nFET semiconductor channel material nanosheet 14 of the plurality of spaced apart nFET semiconductor channel material nanosheets. In such embodiments, a L-shaped stacked FET is provided.

In embodiments of the present application, the Al-containing alloy layer 34 is located between bottom n-type threshold voltage setting work function metal layer 32 and top n-type threshold voltage setting work function metal layer 36.

In embodiments of the present application, the semiconductor device further includes gate dielectric layer 30 having a dielectric constant of 4.0 or greater located between the bottom n-type threshold voltage setting work function metal layer 32 and each nFET semiconductor channel material nanosheet 14 of the plurality of spaced apart nFET semiconductor channel material nanosheets.

In embodiments of the present application, the semiconductor device further includes middle dielectric isolation layer 26 located between the first transistor and the second transistor.

Notably, FIGS. 1A-1D illustrate a semiconductor device that includes a first transistor including a plurality of spaced apart nFET semiconductor channel material nanosheets having Al-containing alloy layer 34 surrounding at least two, but not all, faces of each nFET semiconductor channel material nanosheet 14 of the plurality of spaced apart nFET semiconductor channel material nanosheets; a second transistor stacked over the first transistor in which the second transistor includes a plurality of spaced apart pFET semiconductor channel material nanosheets (i.e., pFET semiconductor channel material nanosheets 20); and middle dielectric isolation layer 26 located between the first transistor and the second transistor.

Notably, FIGS. 2A-2D illustrates a semiconductor device that includes a first transistor including a plurality of spaced apart pFET semiconductor channel material nanosheets (i.e., pFET semiconductor channel material nanosheets 20); a second transistor stacked over the first transistor, in which the second transistor includes a plurality of spaced apart nFET semiconductor channel material nanosheets having Al-containing alloy layer 34 surrounding at least two, but not all, faces of each nFET semiconductor channel material nanosheet 14 of the plurality of spaced apart nFET semiconductor channel material nanosheets; and middle dielectric isolation layer 26 located between the first transistor and the second transistor.

As is shown is FIGS. 1A-1D and 2A-2B, each semiconductor device further includes semiconductor substrate 10 that is located beneath the stacked first and second transistors, gate cut structure 28 that is located adjacent to each side of the stacked first and second transistors, gate electrode 42 that is shared between the stacked first and second transistors, and the first transistor or the second transistor not including the Al-containing alloy layer 34 includes a p-type threshold voltage setting work function metal layer 40 which is spaced apart from each of the pFET semiconductor channel material nanosheets 20 by gate dielectric layer 30. In embodiments, a gate cap 44 can be present on top of gate electrode 42 and each gate cut structure 28.

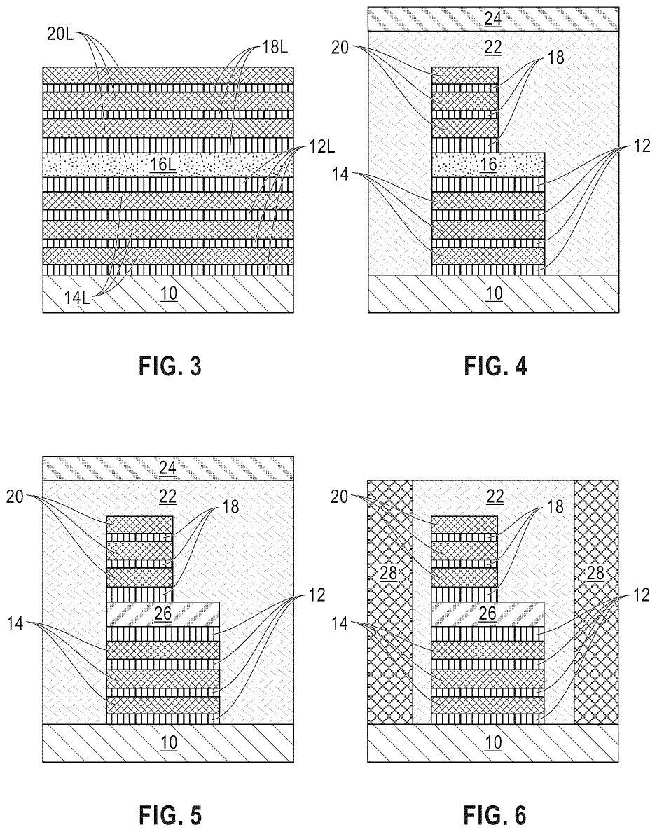

Reference will now be made to FIGS. 3-13 which illustrate a method that can be used in fabricating an exemplary semiconductor device in accordance with the present application. Notably, the method exemplified in FIGS. 3-13 is a method in which a pFET is formed over an nFET. The method can be modified by one skilled in art to form an nFET over a pFET.

The method of the present application begins by providing the initial structure illustrated in FIG. 3. The initial structure illustrated in FIG. 3 includes an nFET material stack of alternating layers of nFET sacrificial semiconductor material layers 12L and nFET semiconductor channel material layers 14L, and a pFET material stack of alternating layers of pFET sacrificial semiconductor material layers 18L and pFET semiconductor channel material layers 20L, in which the nFET material stack is vertically spaced apart from the pFET material stack by a sacrificial semiconductor material layer 16L.

The initial structure further includes semiconductor substrate 10 that is located beneath the nFET material stack. The semiconductor substrate 10 is composed of at least one semiconductor material having semiconducting properties. Illustrative examples of semiconductor materials that can be used in providing the semiconductor substrate 10 include, but are not limited to, silicon (Si), a silicon germanium (SiGe) alloy, a silicon germanium carbide (SiGeC) alloy, germanium (Ge), III/V compound semiconductors or II/VI compound semiconductors. In some embodiments, the semiconductor substrate 10 is entirely composed of one or more semiconductor materials. In other embodiments, the semiconductor substrate 10 can include a buried dielectric layer (e.g., silicon dioxide and/or boron nitride) sandwiched between a semiconductor base layer and a semiconductor device layer.

As mentioned above, the nFET material stack includes alternating layers of nFET sacrificial semiconductor material layers 12L and nFET semiconductor channel material layers 14L. As is illustrated in FIG. 3, the nFET material stack can include “n” number of nFET semiconductor channel material layers 14L and “n+1” number of nFET sacrificial semiconductor material layers 12L, where n is an integer starting from 2, typically n is 3 or more. In the illustrated embodiment, each nFET semiconductor channel material layer 14L is sandwiched between a bottom nFET sacrificial semiconductor material layer and a top nFET sacrificial semiconductor material layer. Each nFET sacrificial semiconductor material layer 12L is composed of a first semiconductor material, while each nFET semiconductor channel material layer 14L is composed of a second semiconductor material. In the present application, the first semiconductor material is compositionally different from the second semiconductor material as well as the uppermost semiconductor material portion of the semiconductor substrate 10. In the illustrated embodiment, the second semiconductor material that provides each nFET semiconductor channel material layer 14L can provide high channel mobility nFET devices (i.e., nFETs). The first semiconductor material that provides each nFET sacrificial semiconductor material layer 12L, and the second semiconductor material that provides each nFET semiconductor channel material layer 14L can include one of the semiconductor materials mentioned above for the semiconductor substrate 10. In one example, the first semiconductor material that provides each nFET sacrificial semiconductor material layer 12L is composed of a silicon germanium alloy having a germanium content from 20 atomic percent to 40 atomic percent and the second semiconductor material that provides each nFET semiconductor channel material layer 14L is composed of silicon.

In the present application, a topmost sacrificial semiconductor material layer present in the nFET material stack is intentionally designed to have a thickness than is greater than a thickness of the remaining nFET sacrificial semiconductor material layers 12L present in the nFET material stack. This provides for increased space within the structure.

The sacrificial semiconductor material layer 16L is composed of a third semiconductor material which is compositionally different from the first semiconductor material that provides each of the nFET sacrificial semiconductor material layers 12L and the second semiconductor material that provides each of the nFET semiconductor channel material layers 14L. In one example, the sacrificial semiconductor material layer 16L is composed of a SiGe alloy in which the germanium content is at least 45 atomic percent or greater.

As mentioned above, the pFET material stack includes alternating layers of pFET sacrificial semiconductor material layers 18L and pFET semiconductor channel material layers 20L. As is illustrated in FIG. 3, the pFET material stack can include “m” number of pFET semiconductor channel material layers 20L and “m+1” number of pFET sacrificial semiconductor material layers 18L, where m is an integer starting from 2, typically m is 3 or more. Each pFET semiconductor channel material layer 20L is sandwiched between a bottom pFET sacrificial semiconductor material layer and a top pFET sacrificial semiconductor material layer. Each of the pFET sacrificial semiconductor material layers 18L is composed of the first semiconductor material mentioned above, while each of the pFET semiconductor channel material layers 20L is composed of a fourth semiconductor material. In the present application, the first semiconductor material is compositionally different from the fourth semiconductor material, and both the first semiconductor material and the fourth semiconductor material are compositionally different from the third semiconductor material that provides the sacrificial semiconductor material layer 16L. The fourth semiconductor material that provides each of the pFET semiconductor channel material layers 20L can be compositionally the same as, or compositionally different from, the second semiconductor material that provides each of the nFET semiconductor channel material layers 14L. In some embodiments, the fourth semiconductor material that provides each pFET semiconductor channel material layer 20L can provide high channel mobility for pFETs. The fourth semiconductor material that provides each of the pFET semiconductor channel material layers 20L can include one of the semiconductor materials mentioned above for the semiconductor substrate 10. In one example, the second semiconductor material that provides each of the pFET sacrificial semiconductor material layers 18L is composed of a silicon germanium alloy having a germanium content from 20 atomic percent to 40 atomic percent and the fourth semiconductor material that provides each of the pFET semiconductor channel material layers 20L is composed of silicon.

In the present application, a bottommost pFET sacrificial semiconductor material layer present in the pFET material stack is intentionally designed to have a thickness than is greater than a thickness of the remaining pFET semiconductor channel material layers 20L present in the pFET material stack. This provides for increased space within the structure.

The nFET material stack (including the alternating layers of nFET sacrificial semiconductor material layers 12L and nFET semiconductor channel material layers 14L), the sacrificial semiconductor material layer 16L and the pFET material stack (including the alternating layers of the pFET sacrificial semiconductor material layers 18L and the pFET semiconductor channel material layers 20L) are patterned layers which collectively form a patterned stack that is formed on the semiconductor substrate 10 by deposition of each layer, followed by lithographically patterning the as-deposited layers. Although a single patterned stack is described and illustrated, a plurality of patterned stacks can be formed. Each patterned stack will be used in defining an active device area in which a stacked FET will be formed. The deposition of each layer can include, for example, chemical vapor deposition (CVD), plasma enhanced chemical vapor deposition (PECVD) and/or epitaxial growth. Throughout the present application, the terms “epitaxial growth” or “epitaxially growing” mean the growth of a semiconductor material on a growth surface of another semiconductor material, in which the semiconductor material being grown has the same crystalline characteristics as the growth surface of the another semiconductor material. In an epitaxial deposition process, the chemical reactants provided by the source gases are controlled and the system parameters are set so that the depositing atoms arrive at the growth surface of the another semiconductor material with sufficient energy to move around on the growth surface and orient themselves to the crystal arrangement of the atoms of the growth surface. Examples of various epitaxial growth process apparatuses that can be employed in the present application include, e.g., rapid thermal chemical vapor deposition (RTCVD), low-energy plasma deposition (LEPD), ultra-high vacuum chemical vapor deposition (UHVCVD), atmospheric pressure chemical vapor deposition (APCVD) and molecular beam epitaxy (MBE). The temperature for epitaxial deposition typically ranges from 450° C. to 900° C. Although higher temperature typically results in faster deposition, the faster deposition may result in crystal defects and film cracking.

Throughout the present application, lithographic patterning denotes a patterning process in which a photoresist material is first formed on a layer or structure that needs to be patterned. The photoresist material can be formed by a deposition process including, for example, CVD, PECVD or spin-on coating. The as-deposited photoresist material is then subjected to a desired pattern of irradiation. The exposed photoresist material is then developed utilizing a conventional resist developer. The etch used in the patterning process can include, for example, a dry etching process, a wet chemical etching process or a combination of dry etching and wet chemical etching. Dry etching can include reactive ion etching (RIE), ion beam etching (IBE) or plasma etching. Although a single patterned stack is described and illustrated, a plurality of patterned stacks can be formed.

Referring now to FIG. 4, there is illustrated the initial structure of FIG. 3 after forming a sacrificial gate structure 22. The sacrificial gate structure 22 includes a sacrificial gate material. The sacrificial gate material can be composed of, for example, polysilicon, amorphous silicon, amorphous silicon germanium, amorphous germanium or a multilayered stack thereof. In some embodiments, a sacrificial dielectric layer (not shown) can be present beneath the sacrificial gate structure 22. When present, the sacrificial dielectric layer can be composed of a sacrificial dielectric material such as, for example, silicon dioxide.

In some embodiments, a sacrificial gate cap 24 can be used and present on top of the sacrificial gate structure 22. When present, the sacrificial gate cap 24 can be composed of a dielectric hard mask material such as, for example, silicon dioxide, silicon nitride and/or silicon oxynitride.

The number of sacrificial gate structures 22 that is formed is not limited so long as at least one sacrificial gate structure is formed that straddles the patterned stack including the nFET material stack, the sacrificial semiconductor material layer 16L and the pFET material stack illustrated in FIG. 3.

Although not shown in the cross sectional view illustrated in FIG. 4, a gate spacer is formed along a sidewall of the sacrificial dielectric layer (if the same is present), along a sidewall of the sacrificial gate structure 22 and, if present, a sidewall of the sacrificial gate cap 24. The gate spacer is composed of a gate spacer material such as, for example, silicon dioxide, SiN, SiBCN, SiOCN or SiOC.

The sacrificial dielectric layer (if the same is present), the sacrificial gate structure 22 and, if present, the sacrificial gate cap 24 can be formed by depositing (e.g., CVD, PECVD, physical vapor deposition (PVD) or atomic layer deposition (ALD)) a blanket layer of sacrificial dielectric material (if the same is present), followed by depositing (e.g., CVD, PECVD, ALD or PVD) a blanket layer of the sacrificial gate material, followed by depositing (e.g., CVD, PECVD, ALD or PVD) a blanket layer of a dielectric hard mask material, if the same is present. Lithographic patterning is then used form the sacrificial dielectric layer (if present), the sacrificial gate structure 22, and the sacrificial gate cap 24 (if the same is present). Gate spacer (not shown) is then formed by deposition of the gate spacer material, followed by a spacer etch.

After forming the gate spacer and as is illustrated in FIG. 4, the nFET material stack, the sacrificial semiconductor material layer 16L, and the second material are etched utilizing the sacrificial gate structure 22 (and the gate spacer) as an etch mask to provide an nFET nanosheet stack of alternating nanosheets of nFET sacrificial semiconductor material nanosheets 12 and nFET semiconductor channel material nanosheets 14, and a pFET nanosheet stack of alternating nanosheets of pFET sacrificial semiconductor material nanosheets 18 and pFET semiconductor channel material nanosheets 20, in which the nFET nanosheet stack is vertically spaced apart from the pFET nanosheet stack by a patterned sacrificial semiconductor material layer 16.

The etch used in forming the nFET nanosheet stack, the patterned sacrificial semiconductor material layer 16, and the pFET nanosheet stack can include any dry etching process and/or chemical wet etching process. Typically, RIE is used during the formation of the nFET nanosheet stack, the patterned sacrificial semiconductor material layer 16, and the pFET nanosheet stack. After this etch, the nFET semiconductor channel material nanosheets 14 and the pFET semiconductor channel material nanosheets 20 have a same length. Such an embodiment is used when a I-shaped stacked FET is to be formed.

In some embodiments, the pFET nanosheet stack can by lithographically patterned to provide a pFET semiconductor channel material nanosheets 20 whose length is less than the nFET semiconductor channel material nanosheets 14. The lithographically patterning of pFET nanosheet stack which is illustrated in FIG. 4 is used in embodiments when a L-Shaped stacked FET is to be formed.

The nFET nanosheet stack includes a remaining (i.e., non-etched) portion of the alternating layers of the nFET sacrificial semiconductor material layers 12L and the nFET semiconductor channel material layers 14L. The remaining (i.e., non-etched) portion of each nFET sacrificial semiconductor material layer 12L is now referred to as an nFET sacrificial semiconductor material nanosheet 12, and the remaining (i.e., non-etched) portion of each nFET semiconductor channel material layer 14L is now referred to as an nFET semiconductor channel material nanosheet 14. The pFET nanosheet stack includes a remaining (i.e., non-etch) portion of the alternating layers of the pFET sacrificial semiconductor material layers 18L and the pFET semiconductor channel material layers 20L. The remaining (i.e., non-etched) portion of each pFET sacrificial semiconductor material layer 18L is now referred to as a pFET sacrificial semiconductor material nanosheet 18, and the remaining (i.e., non-etched) portion of each pFET semiconductor channel material layer 20L is now referred to as a pFET semiconductor channel material nanosheet 20.

In the illustrated embodiment of the present application, the pFET nanosheet is located above the nFET nanosheet stack and the nFET nanosheet stack and the pFET nanosheet stack are spaced apart by the remaining (i.e., non-etched) portion of the sacrificial semiconductor material layer 16L (the remaining (i.e., non-etched) portion of the sacrificial semiconductor material layer 16L is referred to herein as patterned sacrificial semiconductor material layer 16). In some embodiments, the patterned sacrificial semiconductor material layer 16 has a same length as that of the underlying nFET nanosheet stack.

Referring now to FIG. 5, there is illustrated the structure of FIG. 4 after replacing the patterned sacrificial semiconductor material layer 16 with a middle dielectric isolation layer 26. The middle dielectric isolation layer 26 is composed of a dielectric isolation material including, for example, SiBCN, SiOCN or SiOC. The replacing of the patterned sacrificial semiconductor material layer 16 includes an etch, followed by deposition of a dielectric isolation material and an isotropic etch. During this replacement process, each of the nFET and pFET nanosheet stacks are anchored in place by at least the sacrificial gate structure 22 and the gate spacer. The length of the middle dielectric isolation layer can be the same or different from the nFET semiconductor channel material nanosheets 14 and/or the pFET semiconductor channel material nanosheets 20.

Either prior to, or after, replacing the patterned sacrificial semiconductor material layer 16 with the middle dielectric isolation layer 26, inner spacers can be formed in both the nFET and pFET nanosheet stacks. The inner spacers are not illustrated in the cross sectional view provided in the present application. The forming of the inner spacers includes recessing each nFET sacrificial semiconductor material nanosheet 12 and each pFET sacrificial semiconductor material nanosheet 18. The recessing includes a lateral etching process that is selective in partially removing the first semiconductor material that provides each nFET sacrificial semiconductor material nanosheet 12 and each pFET sacrificial semiconductor material nanosheet 18. A gap is formed at each of the ends of each recessed nFET sacrificial semiconductor material nanosheet and at each of the ends of each recessed pFET sacrificial semiconductor material nanosheet. The forming of the inner spacers continues by depositing (e.g., CVD, PECVD, or ALD) a layer of inner dielectric spacer material in each of the gaps and along the sidewall of the first and pFET nanosheet stacks. The inner dielectric spacer material can include, but is not limited to, silicon dioxide, SiN, SiBCN, SiOCN or SiOC. After depositing the layer of inner dielectric spacer material, an isotropic etch back process is performed on the layer of inner dielectric spacer material. This isotropic etch back process removes the layer of inner dielectric spacer material that is present on the sidewalls of the first and pFET nanosheet stacks, while maintaining the layer of inner dielectric spacer material in each gaps. The maintained layer of inner dielectric spacer material within each of the gaps provides the inner spacers.

After forming the inner spacers and replacing the patterned sacrificial semiconductor material layer 16 with the middle dielectric isolation layer 26, nFET source/drain regions and pFET source/drain regions that are vertically spaced apart by a separating dielectric layer are formed (the nFET source/drain regions, the separating dielectric layer, and the pFET source/drain regions are not shown in the cross sectional view of the drawing illustrated in FIG. 5). The nFET source/drain regions are formed adjacent to opposing sides of the nFET nanosheet stack. Each nFET source/drain region is formed outward from each of the physically exposed end sidewalls of the nFET semiconductor channel material nanosheets 14. Each nFET source/drain region is formed by an epitaxial growth process, as defined above, followed by a recess etch. As used herein, a “source/drain” region can be a source region or a drain region depending on subsequent wiring and application of voltages during operation of the FET. Each nFET source/drain region is composed of a fifth semiconductor material and a first dopant. The fifth semiconductor material that provides each nFET source/drain region can be compositionally the same as, or compositionally different from, the second semiconductor material that provides the nFET semiconductor channel material nanosheets 14. The first dopant is an n-type dopant. “N-type” refers to the addition of impurities that contributes free electrons to an intrinsic semiconductor. In a silicon containing semiconductor material, examples of n-type dopants, i.e., impurities, include, but are not limited to, antimony, arsenic and phosphorous. In one example, each nFET source/drain region can have a dopant concentration of from 4×10²⁰ atoms/cm³ to 3×10²¹ atoms/cm³. In one example, each nFET source/drain region is composed of phosphorus doped silicon.

The source/drain separating dielectric layer is composed of a dielectric material such as, for example, silicon dioxide. The source/drain separating dielectric layer can be formed utilizing a deposition process, followed by a recess etch.

The pFET source/drain regions are formed on top of the source/drain separating dielectric layer. Each pFET source/drain region is formed outward from each of the physically exposed end sidewalls of the pFET semiconductor channel material nanosheets 20. Each pFET source/drain region is formed by an epitaxial growth process, as defined above, followed by a planarization process. Each pFET source/drain region is composed of a sixth semiconductor material and a second dopant. The sixth semiconductor material that provides each pFET source/drain region can be compositionally the same as, or compositionally different from, the third semiconductor material that provides the pFET semiconductor channel material nanosheets 20. The second dopant is a p-type dopant. The term “p-type” refers to the addition of impurities to an intrinsic semiconductor that creates deficiencies of valence electrons. In a silicon-containing semiconductor material, examples of p-type dopants, i.e., impurities, include, but are not limited to, boron, aluminum, gallium, and indium. Each pFET source/drain region can have a dopant concentration of from 4×10²⁰ atoms/cm³ to 3×10²¹ atoms/cm³.

Referring now to FIG. 6, there is illustrated the structure of FIG. 5 after performing a gate cut process. The gate cut process employed in the present application includes revealing the sacrificial gate structure 22 by performing a material removal process that is selective in removing the sacrificial gate cap 24 from the structure. This step can be omitted when the sacrificial gate cap 24 is not present. In one example, the removal of the sacrificial gate cap 24 includes a planarization process such as, for example, chemical mechanical planarization (CMP). During the removal of the sacrificial gate cap 24, an upper portion of the gate spacer can be removed. The gate cut process continues by forming an opening in the sacrificial gate structure 22 by lithography and etching. The opening extends entirely through the sacrificial gate structure 22 and, if present, the sacrificial dielectric layer and physically exposes a topmost surface of the semiconductor substrate 10. The gate cut process continues by forming a gate cut structure 28 in the opening. The gate cut structure 28 is composed of one or more dielectric materials such as, for example, silicon dioxide, silicon nitride or silicon oxynitride. The forming of the gate cut structure 28 includes depositing one or more dielectric materials into the opening, and then performing a planarization process such as, for example, CMP.

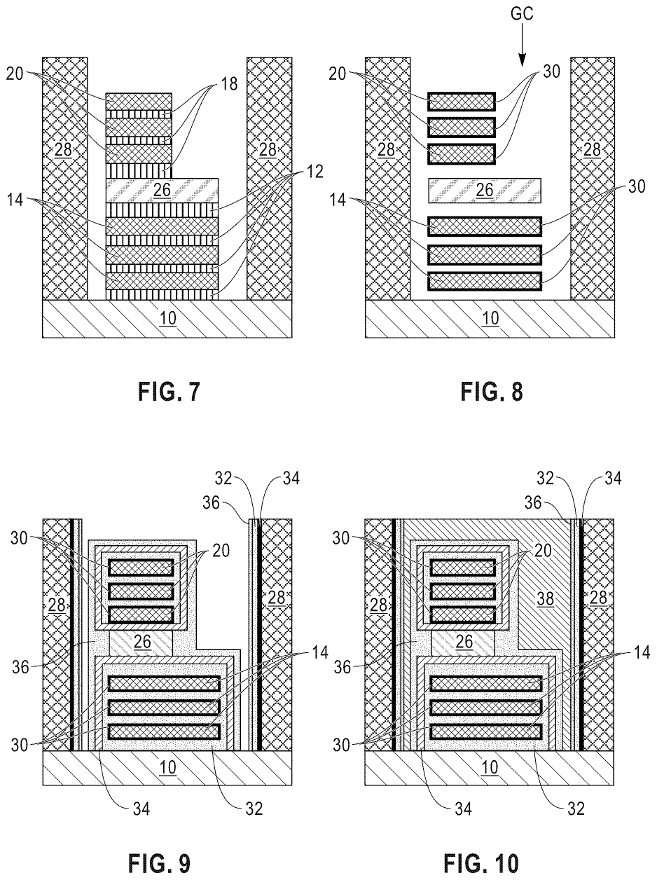

Referring now to FIG. 7, there is illustrated the structure of FIG. 6 after removing the sacrificial gate structure 22. In embodiments in which a sacrificial dielectric layer is also present, the sacrificial dielectric layer is removed at this point of the method of the present application. The sacrificial gate structure 22 and, if present, the sacrificial dielectric layer are removed to reveal the nFET and pFET nanosheets. The sacrificial gate structure 22 and, if present, the sacrificial dielectric layer can be removed utilizing at least one material removal process such as, for example, etching, which is selective in removing the sacrificial gate structure 22 and, if present, the sacrificial dielectric layer. In some embodiments, a first etch is used to remove the sacrificial gate structure 22 and a second etch is used to remove the sacrificial dielectric layer.

Referring now to FIG. 8, there is illustrated the structure of FIG. 7 after removing each of the nFET sacrificial semiconductor material nanosheets 12 and each of the pFET sacrificial semiconductor material nanosheets 18 to suspend a portion of each of the nFET semiconductor channel material nanosheets 14 and each of the pFET semiconductor channel material nanosheets 20, respectively. The suspended portion of each of the nFET semiconductor channel material nanosheets 14 and each of the pFET semiconductor channel material nanosheets 20 represents a channel portion of the suspended semiconductor channel material nanosheets. The removal of each nFET sacrificial semiconductor material nanosheet 12 and each pFET sacrificial semiconductor material nanosheet 18 is performed utilizing any material removal process such as, for example, etching, which is selective in removing the second semiconductor material that was used in providing the nFET sacrificial semiconductor material nanosheets 12 and the pFET sacrificial semiconductor material nanosheets 18. The removal of the nFET sacrificial semiconductor material nanosheets 12 and the pFET sacrificial semiconductor material nanosheets 18 forms a gate cavity, GC. The gate cavity defines a gate active area. In the present application, the gate cavity is located between adjacent gate cut structures 28.

At this point of the present application, the nFET nanosheet stack includes a plurality of spaced apart nFET semiconductor channel material nanosheets and the pFET nanosheet stack includes a plurality of spaced apart pFET semiconductor channel material nanosheets.

Next, and as also shown in FIG. 8, a gate dielectric layer 30 is formed on (i.e., around) a suspended portion of each of the nFET semiconductor channel material nanosheets 14 and each of the pFET semiconductor channel material nanosheets 20. Although not specifically illustrated in FIG. 8, the gate dielectric layer 30 would also be formed along the topmost surface of the semiconductor substrate 10 and along a sidewall of the gate cut structure 28. The gate dielectric layer 30 is composed of a gate dielectric material having a dielectric constant of 4.0 or greater. All dielectric constants mentioned herein are measured in a vacuum unless stated to the contrary. Illustrative examples of gate dielectric materials include, but are not limited to, silicon dioxide, hafnium dioxide (HfO₂), hafnium silicon oxide (HfSiO), hafnium silicon oxynitride (HfSiO), lanthanum oxide (La₂O₃), lanthanum aluminum oxide (LaAlO₃), zirconium dioxide (ZrO₂), zirconium silicon oxide (ZrSiO₄), zirconium silicon oxynitride (ZrSiOₓN_{y}), tantalum oxide (TaOₓ), titanium oxide (TiO), barium strontium titanium oxide (BaO₆SrTi₂), barium titanium oxide (BaTiO₃), strontium titanium oxide (SrTiO₃), yttrium oxide (Yb₂O₃), aluminum oxide (Al₂O₃), lead scandium tantalum oxide (Pb(Sc,Ta)O₃), and/or lead zinc niobite (Pb(Zn,Nb)O). The gate dielectric material can further include dopants such as lanthanum (La), aluminum (Al) and/or magnesium (Mg). The gate dielectric layer 30 can be formed by a deposition process including, but not limited to CVD, PECVD, or ALD. A planarization process can follow the deposition process.

Referring now to FIG. 9, there is illustrated the structure of FIG. 8 after forming a bottom n-type threshold voltage setting work function metal layer 32, an Al-containing alloy layer 34, and a top n-type threshold voltage setting work function metal layer 36. In the present application, the bottom n-type threshold voltage setting work function metal layer 32 is formed on the gate dielectric layer 30, the Al-containing alloy layer 34 is formed on the bottom n-type threshold voltage setting work function metal layer 32, and the top n-type threshold voltage setting work function metal layer 36 is formed on the Al-containing alloy layer 34. At this point of the method of the present application, the bottom n-type threshold voltage setting work function metal layer 32, the Al-containing alloy layer 34, and the top n-type threshold voltage setting work function metal layer 36 are present in a first device area including the nFET semiconductor channel material nanosheets 14 and a second device area including the pFET semiconductor channel material nanosheets 20.

The bottom n-type threshold voltage setting work function metal layer 32 is composed of an n-type work function metal (WFM) that is selected to effectuate an n-type threshold voltage shift. “N-type threshold voltage shift” as used herein means a shift in the effective work-function of the WFM towards a conduction band of silicon in a silicon-containing material. In one embodiment, the work function of the n-type work function metal ranges from 4.1 eV to 4.3 eV. Examples of such materials that can effectuate an n-type threshold voltage shift include, but are not limited to, titanium aluminum, titanium aluminum carbide, tantalum nitride, titanium nitride, hafnium nitride, hafnium silicon, or combinations thereof. The bottom n-type threshold voltage setting work function metal layer 32 can be formed by a deposition process including, for example, CVD, PECVD or ALD. A planarization process can follow the deposition of the n-type work function metal.

The top n-type threshold voltage setting work function metal layer 36 is composed of a n-type WFM that can be compositionally the same as, or compositionally different from, the n-type work function metal that provides the bottom n-type threshold voltage setting work function metal layer 32. In one example, the bottom n-type threshold voltage setting work function metal layer 32 and the top n-type threshold voltage setting work function metal layer 36 are both composed of TiN. The top n-type threshold voltage setting work function metal layer 36 can be formed by a deposition process including, for example, CVD, PECVD or ALD. A planarization process can follow the deposition of the n-type work function metal.

The Al-containing alloy layer 34 is composed of an Al-containing alloy such as, for example, TaAlC or TiAlC that removes oxygen from the gate dielectric layer 30 and it can further be used to set the threshold voltage of an nFET. The Al-containing alloy layer 34 can be formed by a deposition process including, for example, CVD, PECVD or ALD. In the present application, the Al-containing alloy layer 34 surrounds at least two faces of the nFET semiconductor channel material nanosheets 14, but not all four faces of the each of the nFET semiconductor channel material nanosheets 14. In the illustrated embodiment, the Al-containing alloy layer 34 surrounds two surfaces of each of the nFET semiconductor channel material nanosheets 14. A planarization process can follow the deposition of the Al-containing alloy.

Referring now to FIG. 10, there is illustrated the structure of FIG. 9 after forming an organic dielectric layer 38. The organic dielectric layer 38 is composed of an organic dielectric material such as, for example, an organic planarization dielectric material. The organic dielectric layer 38 can be formed by a deposition process such as, for example, CVD, PECVD or spin-on containing. A planarization process can follow the deposition of the organic dielectric material.

Referring now to FIG. 11, there is illustrated the structure of FIG. 10 after recessing the organic dielectric layer 38 to physically expose the second device area including the pFET nanosheet stack. The recessing of the organic dielectric layer 38 includes a recessing etching process that is selective in removing organic dielectric material from the structure. The organic dielectric layer 38 remains in the first device area including the nFET nanosheet stack, the bottom n-type threshold voltage setting work function metal layer 32, the Al-containing alloy layer 34, and the top n-type threshold voltage setting work function metal layer 36.

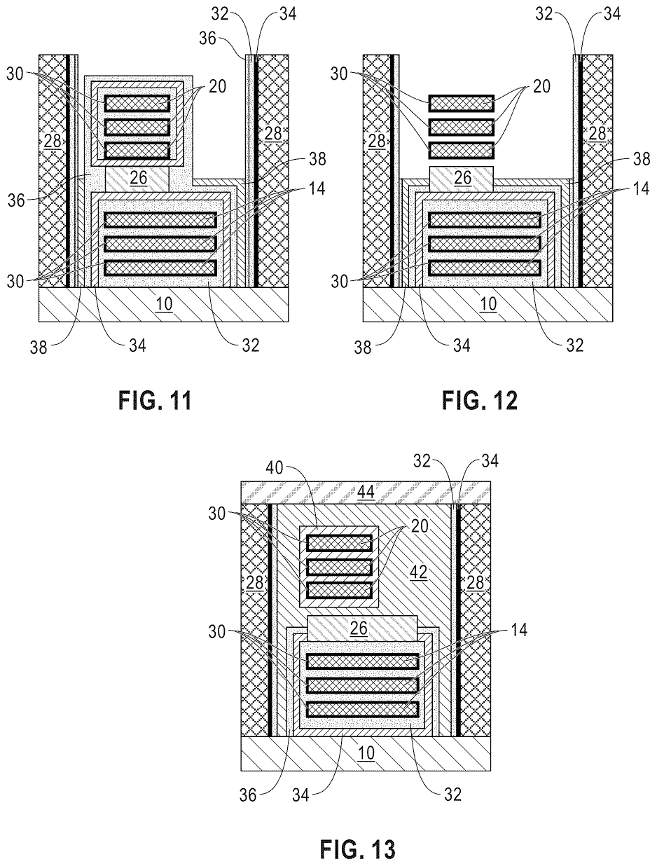

Referring now to FIG. 12, there is illustrated the structure of FIG. 11 after removing the top n-type threshold voltage setting work function metal layer 36, the Al-containing alloy layer 34, and the bottom n-type threshold voltage setting work function metal layer 32 from the second device area. The removal of top n-type threshold voltage setting work function metal layer 36, the Al-containing alloy layer 34, and the bottom n-type threshold voltage setting work function metal layer 32 from the second device area can be performed utilizing one, two or three material removal processes that is (are) selective in removing the top n-type threshold voltage setting work function metal layer 36, the Al-containing alloy layer 34, and the bottom n-type threshold voltage setting work function metal layer 32 from the second device area. The removal process (or processes) stops on the gate dielectric layer 30 that surrounds the pFET semiconductor channel material nanosheets 20 of the pFET nanosheet stack.

Referring now to FIG. 13, there is illustrated the structure of FIG. 12 after forming a p-type threshold voltage setting work function metal layer 40, removing a remaining portion of the organic dielectric layer 38, and then forming a gate electrode 42 and a gate cap 44. The p-type threshold voltage setting work function metal layer 40 is formed around the pFET semiconductor channel material nanosheets 20 of the pFET nanosheet stack, and on the gate dielectric layer 30. The p-type threshold voltage setting work function metal layer 40 is composed of a p-type WFM that is selected to effectuate a p-type threshold voltage shift. In one embodiment, the work function of the p-type work function metal ranges from 4.9 eV to 5.2 eV. The term “p-type threshold voltage shift” as used herein means a shift in the effective work-function of the p-type work function metal towards a valence band of silicon in the silicon containing material. Examples of such materials that can effectuate a p-type threshold voltage shift include, but are not limited to, titanium nitride, and tantalum carbide, hafnium carbide, and combinations thereof. The-type threshold voltage setting work function metal layer 40 can be formed by a deposition process including, for example, CVD, PECVD or ALD. A planarization process can follow the deposition of the p-type work function metal

After forming the p-type threshold voltage setting work function metal layer 40, the remaining portion of the organic dielectric layer 38 is removed utilizing a material removal process that is selective in removing the organic dielectric material that provides the organic dielectric layer 38 from the structure.

After removing the remaining portion of the organic dielectric layer 38, gate electrode 42 is formed. Gate electrode 42 is a common gate electrode that is shared in the stacked FET of the present application. Gate electrode 42 is composed of a conductive metal including, but not limited to, aluminum (Al), tungsten (W), or cobalt (Co). The gate electrode 42 can be formed by deposition of the conductive metal, followed by planarization.

Gate cap 44 is then formed on top of at least the gate electrode 42. The gate cap 44 can be composed of one of the dielectric hard mask materials mentioned above for the sacrificial gate cap 24. The gate cap 44 can be formed by a deposition process.

Notably, FIG. 13 illustrates a semiconductor device that includes a first transistor including a plurality of spaced apart pFET semiconductor channel material nanosheets (i.e., pFET semiconductor channel material nanosheets 20); a second transistor stacked over the first transistor, in which the second transistor includes a plurality of spaced apart nFET semiconductor channel material nanosheets having Al-containing alloy layer 34 surrounding at least two, but not all, faces of each nFET semiconductor channel material nanosheet 14 of the plurality of spaced apart nFET semiconductor channel material nanosheets; and middle dielectric isolation layer 26 located between the first transistor and the second transistor.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. A semiconductor device comprising:
a second transistor stacked over a first transistor, wherein one of the first transistor or the second transistor comprises a plurality of spaced apart nFET semiconductor channel material nanosheets having an Al-containing alloy layer surrounding at least two, but not all, faces of each nFET semiconductor channel material nanosheet of the plurality of spaced apart nFET semiconductor channel material nanosheets.

2. The semiconductor device of claim 1, wherein the first transistor comprises the Al-containing alloy layer.

3. The semiconductor device of claim 1, wherein the second transistor comprises the Al-containing alloy layer.

4. The semiconductor device of claim 1, wherein the Al-containing alloy layer surrounds three faces of each nFET semiconductor channel material nanosheet.

5. The semiconductor device of claim 1, wherein the first transistor or the second transistor not including the Al-containing alloy layer comprises a plurality of spaced apart pFET semiconductor channel material nanosheets, wherein each pFET semiconductor channel material nanosheet of the plurality of spaced apart pFET semiconductor channel material nanosheets has a same length as each nFET semiconductor channel material nanosheet of the plurality of spaced apart nFET semiconductor channel material nanosheets.

6. The semiconductor device of claim 1, wherein the first transistor or the second transistor not including the Al-containing alloy layer comprises a plurality of spaced apart pFET semiconductor channel material nanosheets, wherein each pFET semiconductor channel material nanosheet of the plurality of spaced apart pFET semiconductor channel material nanosheets has a length that differs from a length of each nFET semiconductor channel material nanosheet of the plurality of spaced apart nFET semiconductor channel material nanosheets.

7. The semiconductor device of claim 1, wherein the Al-containing alloy layer is located between a bottom n-type threshold voltage setting work function metal layer and a top n-type threshold voltage setting work function metal layer.

8. The semiconductor device of claim 7, further comprising a gate dielectric layer having a dielectric constant of 4.0 or greater located between the bottom n-type threshold voltage setting work function metal layer and each nFET semiconductor channel material nanosheet of the plurality of spaced apart nFET semiconductor channel material nanosheets.

9. The semiconductor device of claim 1, further comprising a middle dielectric isolation layer located between the first transistor and the second transistor.

10. A semiconductor device comprising:
a first transistor comprising a plurality of spaced apart nFET semiconductor channel material nanosheets having an Al-containing alloy layer surrounding at least two, but not all, faces of each nFET semiconductor channel material nanosheet of the plurality of spaced apart nFET semiconductor channel material nanosheets;
a second transistor stacked over the first transistor, wherein second transistor comprises a plurality of spaced apart pFET semiconductor channel material nanosheets; and
a middle dielectric isolation layer located between the first transistor and the second transistor.

11. The semiconductor device of claim 10, wherein the Al-containing alloy layer surrounds three faces of each nFET semiconductor channel material nanosheet.

12. The semiconductor device of claim 10, wherein each pFET semiconductor channel material nanosheet of the plurality of spaced apart pFET semiconductor channel material nanosheets has a same length as each nFET semiconductor channel material nanosheet of the plurality of spaced apart nFET semiconductor channel material nanosheets.

13. The semiconductor device of claim 10, wherein each pFET semiconductor channel material nanosheet of the plurality of spaced apart pFET semiconductor channel material nanosheets has a length that is less than each nFET semiconductor channel material nanosheet of the plurality of spaced apart nFET semiconductor channel material nanosheets.

14. The semiconductor device of claim 10, wherein the Al-containing alloy layer is located between a bottom n-type threshold voltage setting work function metal layer and a top n-type threshold voltage setting work function metal layer, and wherein a gate dielectric layer having a dielectric constant of 4.0 or greater is located between the bottom n-type threshold voltage setting work function metal layer and each nFET semiconductor channel material nanosheet of the plurality of spaced apart nFET semiconductor channel material nanosheets.

15. A semiconductor device comprising:
a first transistor comprising a plurality of spaced apart pFET semiconductor channel material nanosheets;
a second transistor stacked over the first transistor, wherein the second transistor comprises a plurality of spaced apart nFET semiconductor channel material nanosheets having an Al-containing alloy layer surrounding at least two, but not all, faces of each nFET semiconductor channel material nanosheet of the plurality of spaced apart nFET semiconductor channel material nanosheets; and
a middle dielectric isolation layer located between the first transistor and the second transistor.

16. The semiconductor device of claim 15, wherein the Al-containing alloy layer surrounds three faces of each nFET semiconductor channel material nanosheet.

17. The semiconductor device of claim 15, wherein each pFET semiconductor channel material nanosheet of the plurality of spaced apart pFET semiconductor channel material nanosheets has a same length as each nFET semiconductor channel material nanosheet of the plurality of spaced apart nFET semiconductor channel material nanosheets.

18. The semiconductor device of claim 15, wherein each pFET semiconductor channel material nanosheet of the plurality of spaced apart pFET semiconductor channel material nanosheets has a length that is less than each nFET semiconductor channel material nanosheet of the plurality of spaced apart nFET semiconductor channel material nanosheets.

19. The semiconductor device of claim 15, wherein the Al-containing alloy layer is located between a bottom n-type threshold voltage setting work function metal layer and a top n-type threshold voltage setting work function metal layer, and wherein a gate dielectric layer having a dielectric constant of 4.0 or greater is located between the bottom n-type threshold voltage setting work function metal layer and each nFET semiconductor channel material nanosheet of the plurality of spaced apart nFET semiconductor channel material nanosheets.
